(19) United States
(12) Patent Application Publication
(10) Pub. No.: US 2008/0177414 A1
(43) Pub. Date: Jul. 24, 2008

(54) Gas purge method and apparatus

(76) Inventors: Erez Harel, Misgav (IL); Eyal Gardi, En Harod Ihud (IL)

Correspondence Address: Pearl Cohen Zedek Latzer, LLP, 1500 Broadway, 12th Floor, New York, NY, 10036, US

(21) Appl. No.: 11/987,839

(22) Filed: Dec. 5, 2007

(30) Foreign Application Priority Data
Jan. 22, 2007 (IL) 180875

(51) Int. Cl. G06F 19/00

(52) U.S. Cl. 700/121

(57) ABSTRACT

The present invention relates to the removal of a gas or of a gas mixture from a closed container.

More particularly, the invention provides a method and apparatus particularly useful in the production of semiconductors, for automatically and economically purging a first gas or gas mixture from a closed container.

The present invention achieves the above object by providing a method and an apparatus, particularly useful in the production of semiconductors, for automatically and economically purging a first gas or mixture from a closed container, said method having the following steps:
step a: providing equipment including
a first sensor in fluid communication with the outlet of said container;
a source of a second compressed gas suitable for purging said first gas;
at least one remotely controllable inlet valve disposed between said source of said compressed gas and the inlet of said container;
a flow restrictor disposed in said outlet of said container;
an electronic controller connected to and able to receive data from said first sensor and able to control at least one said inlet valve according to a predetermined program relating valve opening to time and to data from said first sensor;
step b: sending a start signal, which optionally may be generated automatically, to said electronic controller;
step c: start releasing said second gas into said container, the flow rate being controlled by said electronic controller;
step d: measuring a parameter of interest by means of a first sensor at the outlet of said container and sending data relating to said parameter to said controller; and
step e: adjusting inlet flow in relation to purging progress.

### CROSS REFERENCE TO RELATED APPLICATIONS

This application claims priority from Israeli Patent Application Number 180875, filed on Jan. 22, 2007, which is incorporated in its entirety herein by reference.

### FIELD OF THE INVENTION

The present invention relates to the removal of a gas or of a gas mixture from a closed container.

More particularly, the invention provides a method and apparatus particularly useful in the production of semiconductors, for automatically and economically purging a first gas or gas mixture from a closed container.

### BACKGROUND OF THE INVENTION

Valuable articles or articles that are irreplaceable but which are to be preserved, for example old documents or exceptionally valuable paintings or a world standard item such as a kilogram weight are best preserved in an inert atmosphere such as in a vacuum or in an inert gas such as Nitrogen, carbon dioxide or helium. In particular during the manufacture of semi-conductors, the wafers being processed must, at some stages of manufacture be protected from oxygen, water vapor, other hazardous gasses and of course airborne particles. The use of clean rooms is often inadequate because the clean air therein contains oxygen water vapor, other hazardous gasses and of course airborne particles. With each generation of integrated circuits having increasingly smaller transistors and other components, the provision of work and storage spaces having clean, inert surroundings becomes ever more important.

The requirement for a purged space also extends to other processes, for example chemical vapor deposition, physical vapor deposition, ion implantation, etching, lithography, chemical mechanical polishing and/or testing.

The factor of concern, for example Oxygen content, relative humidity, pressure differential between the inside and outer side of the container holding the work piece is monitored only occasionally, and the controlling factor is only time. An example of this is seen in US Patent Application No. 2005/0228530, wherein Chang et al. disclose a system for manufacturing IC devices including an operating control system, an intermediate station and one or more gas purge devices.

Robertson Jr. et al. disclose a docking and environmental purging system for IC wafer transfer assemblies in U.S. Pat. No. 6,120,371. The patent is focused on the problems of docking a modular isolation container carrier to a docking station.

In U.S. Pat. No. 6,698,469 B2 Sakamoto et al. disclose a cylinder cabinet and a method for purging the remaining gas in the pipe thereof. Gas remaining in the primary pipe is pumped to a vacuum generator. Gas remaining in the primary pipe is purged as exhaust gas by automatically repeating leaving-pipe-in-pressurized-state purge for pressurizing the inside of the primary pipe by the inert gas and leaving the pipe in this state for 2-10 minutes, and evacuating the pipe for 20 seconds.

The primary shortcoming of prior art devices is that there is no feedback of progress to the devices controlling the purge process. This lack leads to wasting the purging gas, and absorbing more time than necessary—this being a serious shortcoming when the purging process is carried out at a station of an assembly line.

### OBJECTS OF THE INVENTION

It is therefore the object of the present invention to obviate the disadvantages of prior art devices and to provide a purging system which will operate using minimum quantities of purging gas and complete this task in the least possible time.

### SUMMARY OF THE INVENTION

The present invention achieves the above object by providing a method and an apparatus, particularly useful in the production of semiconductors, for automatically and economically purging a first gas or mixture from a closed container, said method having the following steps:

step a: providing equipment including

a first sensor in fluid communication with the outlet of said container;

a source of a second compressed gas suitable for purging said first gas;

at least one remotely controllable inlet valve disposed between said source of said compressed gas and the inlet of said container;

a flow restrictor disposed in said outlet of said container;

an electronic controller connected to and able to receive data from said first sensor and able to control at least one said inlet valve according to a predetermined program relating valve opening to time and to data from said first sensor;

step b: sending a start signal, which optionally may be generated automatically, to said electronic controller;

step c: start releasing said second gas into said container, the flow rate being controlled by said electronic controller;

step d: measuring a parameter of interest by means of a first sensor at the outlet of said container and sending data relating to said parameter to said controller; and

step e: adjusting inlet flow in relation to purging progress.

### PREFFERED EMBODIEMTS OF THE INVENTION

In preferred embodiments of the present invention there is provided a method wherein said parameter is the oxygen content in said container outlet, or the humidity in said container outlet, or the nitrogen content in said container outlet, or the gas pressure in said container outlet.

In a further preferred embodiment of the present invention there is provided a method wherein both a high flow and a low flow inlet conduits are installed in parallel and the high flow inlet is closed after the purge process has achieved a predetermined percentage of completion.

In a preferred embodiment of the present invention there is provided a method wherein said second gas is nitrogen or clean dry air.

In a further preferred embodiment of the method of the present invention there is provided a method wherein fast purging is required and the gas outlet flow is also controlled, said outlet being opened at the start of purging and being at least partly closed after the purge process has achieved a predetermined percentage of completion.

In a preferred embodiment of the apparatus of the present invention there is provided a purging system particularly useful in the production of semiconductors, for automatically and economically purging at least one first gas from a closed container, said system comprising:

a first sensor in fluid communication with the outlet of said container;

a source of a second compressed gas suitable for purging said first gas;

at least one remotely controllable inlet valve disposed between said source of said compressed gas and the inlet of said container;

a flow restrictor disposed in said outlet of said container; and

an electronic controller connected to and able to receive data from said first sensor and able to control at least one inlet valve according to a predetermined program relating valve opening to time and to data from said first sensor.

In a further preferred embodiment of the apparatus of the present invention there is provided a purging apparatus wherein said container comprises a semiconductor wafer carrier and a removable nest docked to said wafer carrier, and a second sensor is provided to signal that said wafer carrier is correctly docked to said nest, said signal being understood by said electronic controller to start the purge process.

In another preferred embodiment of the apparatus of the present invention there is provided a purging system wherein said electronic controller is connectable to a central computer.

In another preferred embodiment of the apparatus of the present invention there is provided a purging system, wherein a mass flow controller is connected to said container inlet.

In a most preferred embodiment of the apparatus of the present invention there is provided purging system further provided with a particle measurement device in fluid communication with said container outlet.

It will thus be realized that the novel method of the present invention provides feedback control of the parameter being measured in the container. Thus, when the system has reached a predefined low level of the gas to be purged, or a high enough level of the gas used for purging, flow of the latter is immediately reduced to the low maintenance level of gas flow. While the saving in purging gas is obvious, equally important is the saving in time of the work to be carried out at this stage of a process, as a whole production line can be slowed down according to the time taken by the slowest stage. One more added value may be the “process repeatability”. Due to deferent process parameters the purge curve may vary from one production lot to the other. With the new “Process Control” the variability between different processes can be minimized, can be monitored and recorded for later on investigation/failure analysis.

A test method to assure correct functioning of the apparatus will also be described.

### BRIEF DESCRIPTION OF THE DRAWINGS

The invention will now be described further with reference to the accompanying drawings, which represent by example preferred embodiments of the invention. Structural details are shown only as far as necessary for a fundamental understanding thereof. The described examples, together with the drawings, will make apparent to those skilled in the art how further forms of the invention may be realized.

In the drawings:

FIG. 1 is a simplified diagrammatic representation of a preferred embodiment of the apparatus according to the invention;

FIG. 2 is a diagrammatic representation of a second preferred embodiment showing the parallel inlet valves;

FIG. 3 is a diagrammatic representation of a further preferred embodiment showing further features such as a presence sensor;

FIG. 4 is a diagrammatic representation of a further preferred embodiment showing a fast discharge valve;

FIG. 5 is a view of a preferred embodiment including a particle measurement device;

FIG. 6 is a plan view of the embodiment referred to in FIG. 2; and

FIG. 7 is a graph showing the progress of the purging operation.

For easier understanding of the method of the present invention the apparatus 10 will be described in this order: apparatus, purge method, and test method.

The following description refers to the manufacture of semi-conductors but is not limited to this application.

In the manufacture of semi-conductors the container being purged may be referred to as a wafer carrier removably connected to a nest.

### DETAILED DESCRIPTION OF THE PREFERRED EXEMPLARY EMBODIMENTS

There is seen in FIG. 1 a simplified diagram of a gas purging apparatus. A wafer carrier 12 is docked to a nest 14. A feedback loop 16 is seen connecting the nest outlet port 18 to the nest inlet port 20. The loop 16 includes an outlet sensor 22, a programmed electronic controller (PEC) 24, and a flow control valve 26 directing an inert second gas 28, typically Nitrogen, to the nest inlet port 20. The first gas 30 which is to be purged from the wafer is usually air possibly including water vapor.

With reference to the rest of the figures, similar reference numerals have been used to identify similar parts.

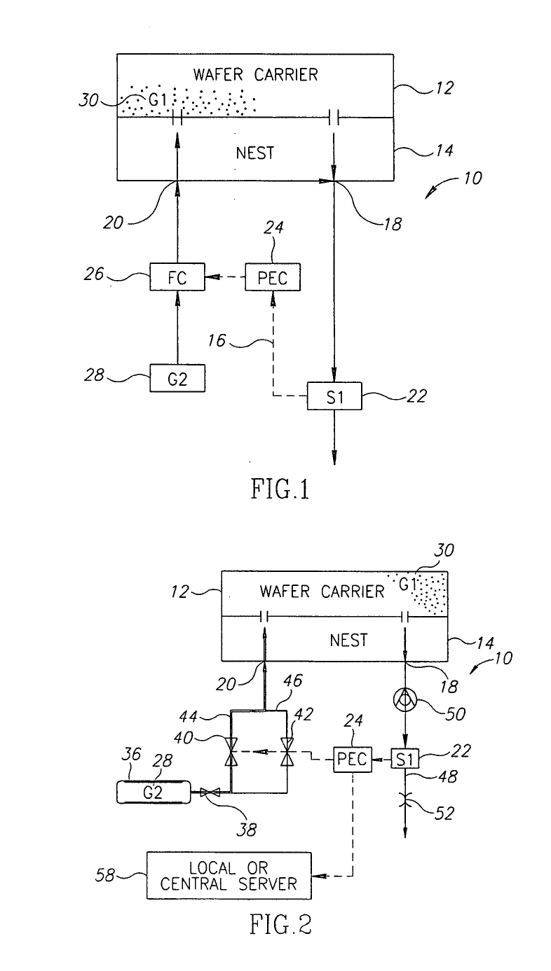

Seen in FIG. 2 are further details of an apparatus 32 similar to 10 seen in FIG. 1. The apparatus 32 carries a pressurized vessel 36 provided with a gas outlet 38. As the pressurized vessel 36 may be mobile or gas supply line from the I/C manufacturer facility, the vessel 36 is in the form of a bottle of a size which can easily be hand held. The compressed (second) gas 28 is typically clean dry air or Nitrogen. The first (to be expelled) gas 30 is typically air.

Two remotely controllable flow control valves 40, 42 are disposed, one each in parallel lines 44, 46 between the pressurized gas supply 36 which is the source of the compressed (second) gas 28 and the inlet port 20 of the nest 14. The sensor 22 is in fluid communication with the nest outlet port 18.

With regard to the nest outlet line 48, means such as the one-way valve 50 seen are optionally provided to prevent re-entry of air to the nest 14 and thus to the wafer carrier 12 via the nest outlet port 18. The valve 50 is however not needed if, as is highly desirable, the gas pressure inside the nest 14 exceeds atmospheric pressure. A flow restrictor 52 is disposed in the outlet line 48 to maintain a pressure differential with room pressure.

The PEC 24 is programmed for execution of the method to be described. The PEC 24 is in electrical connection and receives data from the sensor 22. The PEC 24 processes this data and calculates according to a program previously loaded therein when to close/open the valves 40, 42. The PEC 24 then generates signals to assure the appropriate settings for both the high-flow and the low-flow inlet valves 40, 42, and repeats these calculations every few seconds or less.

In the preferred embodiment seen the PEC 24 exchanges data with a central computer or server 58.

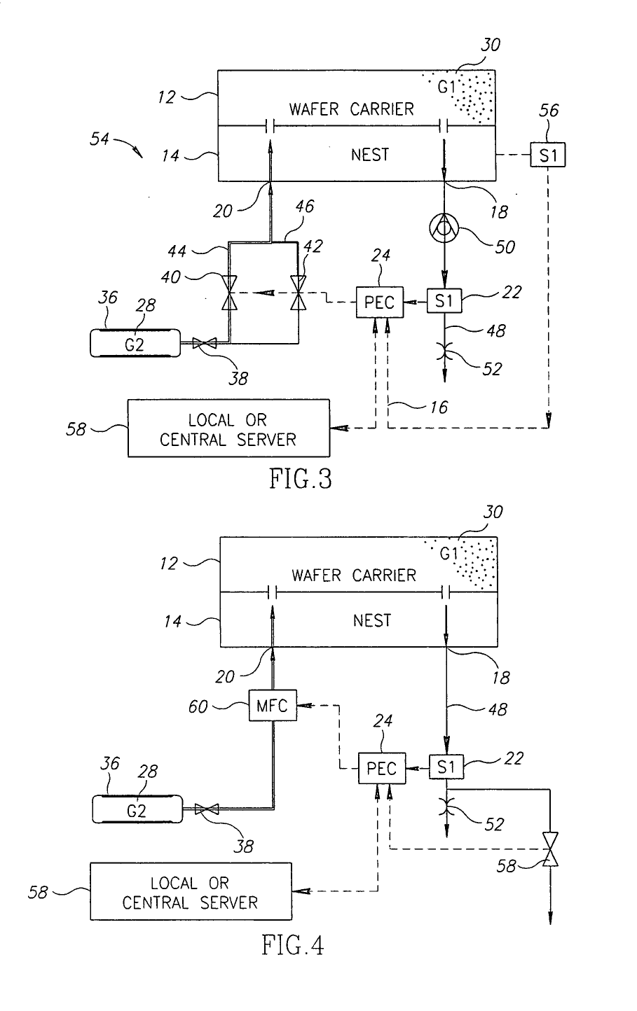

Referring now to FIG. 3, there is seen a purging apparatus 54 wherein a second sensor 56 is provided, which is responsive to the nest 14 being correctly docked. Secure docking results in the sensor 56 sending a signal to the PEC 24, the signal being understood by the PEC 24 to start the purge process.

FIG. 4 illustrates a further embodiment 54. A mass flow controller (MFC) 60 is connected to the nest inlet port 20 instead of the valves 40, 42 which are not needed. Also seem is a third valve 58 connected to the nest outlet, which can be opened at the beginning of the purge process to reduce purge time. The valve is however closed by the PEC 24 a few seconds after starting to prevent excessive loss of the second gas 28.

Seen in FIG. 5 is an apparatus 63 optionally provided with a particle measurement device 64 in fluid communication with the nest outlet port 18. The device 64 is useful in combination with a Quality Assurance program. If particles density of a size larger than a preset limit are detected or a specific material composition is detected an alarm will be activated and a warning message will be sent to the factory host computer and appear on a screen 66 electrically connected to the PEC 24.

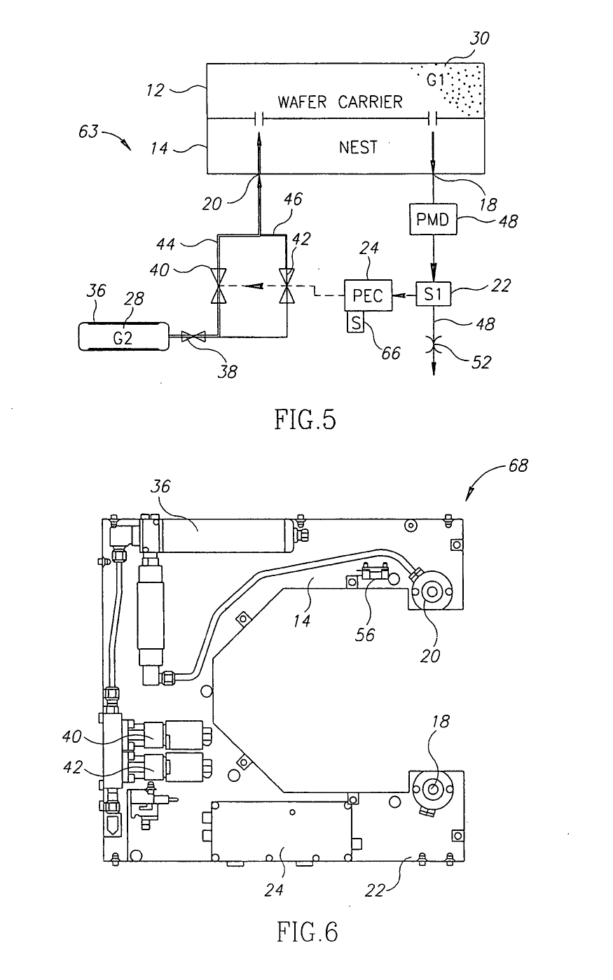

Referring now to FIG. 6, there is depicted a practical embodiment 68, for reference only. No additional novelty is intended to be shown in this figure.

With regard to the method of the invention, reference will be made to the apparatus described and components thereof, particularly with reference to FIG. 3.

A method, particularly useful in the production of semiconductors, for automatically and economically purging a first gas or mixture from a closed container or nest, said method having the following steps:

step a: providing equipment including

a first sensor 22 in fluid communication with the outlet of a vessel 48 containing a first gas 30 to be removed;

a source 36 of a second compressed inert gas 28 suitable for purging said first gas 30;

at least one remotely controllable inlet valve 40 disposed between said source of said compressed second gas 28 and the inlet 20 of said container 12, 14;

a flow restrictor 52 disposed in said outlet of said container; and

electronic control means 24 connected to and able to receive data from said first sensor 22 and able to control at least one said inlet valves 40, 42 according to a predetermined program relating valve opening to time and to data from said first sensor 22;

step b: sending a start signal, which optionally may be generated automatically, to said electronic controller 24;

step c: starting controlled release of said second gas 28 into said container 12 (nest 14);

step d: measuring a parameter of interest at the outlet 18 of said container 12, 14 and sending data relating to said parameter to said control means 24; and

step e: automatically adjusting inlet flow in relation to purging progress.

The first gas 30 to be removed from the container 12, 14 and to be monitored could be oxygen, water vapor, other gasses been or air.

In step d, the parameter being monitored could be second gas content (nitrogen or helium) or gas pressure.

Step e can be executed by providing both a high flow and a low flow source connected in parallel for the passage of the second gas 28. Step e then operates as follows:

e1. Opening both inlet valves 40, 42, and also opening the discharge valve 58 (in FIG. 4) where fast purging is needed.

e2. Closing the discharge valve 58.

e3. After approaching a predetermined percentage of completion, closing the low flow inlet valve 42.

e4. Opening the low flow valve 42 and closing the high flow valve 40 to maintain the quality of the gas in the container being purged as long as necessary.

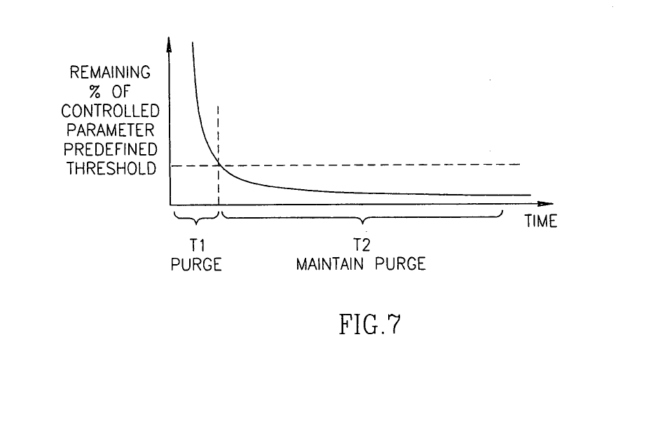

The process is illustrated graphically in FIG. 7.

In step a1 the inert second gas may be nitrogen, clean dry air, carbon dioxide or helium.

With regard to the inspection device, this is identical to the nest seen in FIG. 6, although the inspection device is additionally provided with a plurality of measuring instruments to record time, gas pressures and the percentage of the first gas remaining in the container being purged.

The scope of the described invention is intended to include all embodiments coming within the meaning of the following claims. The foregoing examples illustrate useful forms of the invention, but are not to be considered as limiting its scope, as those skilled in the art will be aware that additional variants and modifications of the invention can readily be formulated without departing from the meaning of the following claims.

We claim:

1. A method, particularly useful in the production of semiconductors, for automatically and economically purging a first gas or mixture from a closed container or nest, said method having the following steps:
step a: providing equipment including
a first sensor in fluid communication with the outlet of said container;
a source of a second compressed gas suitable for purging said first gas;
at least one remotely controllable inlet valve disposed between said source of said compressed gas and the inlet of said container;
a flow restrictor disposed in said outlet of said container; and
an electronic control means connected to and able to receive data from said first sensor and able to control at least one said inlet valve according to a predetermined program relating valve opening to time and to data from said first sensor;
step b: sending a start signal, which optionally may be generated automatically, to said electronic controller;
step c: start releasing said second gas into said container (nest), the flow rate being controlled by valves activated by said electronic control means;
step d: measuring a parameter of interest by means of a first sensor at the outlet of said container and sending data relating to said parameter to said control means; and
step e: adjusting, by means of signals issued by said electronic control means the opening/closing of said remotely controllable inlet valve.

2. The method as claimed in claim 1, wherein said parameter is the oxygen content in said container outlet.

3. The method as claimed in claim 1, wherein said parameter is the humidity in said container outlet.

4. The method as claimed in claim 1, wherein said parameter is the nitrogen content in said container outlet.

5. The method as claimed in claim 1, wherein said parameter is the gas pressure in said container outlet.

6. The method as claimed in claim 1, wherein both a high flow and a low flow inlet conduit are installed in parallel and the high flow inlet is closed after the purge process has achieved a predetermined percentage of completion.

7. The method as claimed in claim 1 wherein said second gas is nitrogen.

8. The method as claimed in claim 1 wherein said second gas is clean dry air.

9. The method as claimed in claim 1 wherein fast purging is required and the gas outlet flow is also controlled, said outlet being opened at the start of purging and being at least partly closed after the purge process has achieved a predetermined percentage of completion.

10. A test method for intermittent checking of the correct operation of said purge method, wherein a wafer carrier is instrumented to monitor progress and effectiveness of said purge method.

11. A purging system particularly useful in the production of semiconductors, for automatically and economically purging at least one first gas from a closed container, said system comprising
a first sensor in fluid communication with the outlet of said container;
a source of a second compressed gas suitable for purging said first gas;
at least one remotely controllable inlet valve disposed between said source of said compressed gas and the inlet of said container;
a flow restrictor disposed in said outlet of said container;
an electronic controller connected to and able to receive data from said first sensor and able to control at least one inlet valve according to a predetermined program relating valve opening to time and to data from said first sensor.

12. A purging system as claimed in claim 11, wherein said container comprises a semiconductor wafer carrier and a removable nest docked to said wafer carrier, and a second sensor is provided to signal that said wafer carrier is correctly docked to said nest, said signal being understood by said electronic controller to start the purge process.

13. A purging system as claimed in claim 11, wherein said electronic controller is connectable to a central computer.

14. A purging system as claimed in claim 11, wherein a mass flow controller is connected to said container inlet.

15. A purging system as claimed in claim 11, further provided with a particle measurement device in fluid communication with said container outlet.
